(19) United States
(12) Patent Application Publication
(10) Pub. No.: US 2005/0044701 A1
(43) Pub. Date: Mar. 3, 2005

(54) Method and device for forming an interposer for a glass and plate

(76) Inventor: Leo C. Comeaux, Lake Charles, LA (US)

Correspondence Address: Charles Brantley, 2686 E. Green Canyon Dr., Meridian, ID, 83642, US

(21) Appl. No.: 10/919,058

(22) Filed: Aug. 16, 2004

Related U.S. Application Data
(60) Provisional application No. 60/498,245, filed on Aug. 27, 2003.

(51) Int. Cl. H05K 3/00

(52) U.S. Cl. 29/829; 29/830; 29/831; 174/261

(57) ABSTRACT

A device is provided that allows for the formation of an interposer for a glass and plate. In one exemplary embodiment, the device is a sheet comprising a printable layer adhered to a non-slip layer. The sheet is configured to accommodate a printer and may in fact receive printing therefrom. The interposer may subsequently be removed from the sheet. The sheet may have also previously received other printing while part of a larger sheet. Printing, perforating, complete cutting, and assembling component materials maybe segmented and interleaved as preferred.

### FIELD OF THE INVENTION

The present invention relates to a method and device for forming an interposer for a glass and plate, wherein the interposer is configured to enable a user to hold both the plate and glass simultaneously with only one hand.

### DESCRIPTION OF THE RELATED ART

Embodiments of the current invention are related to matters addressed in U.S. Pat. No. 6,138,860 and its continuation, U.S. App. Ser. No. 09/676,281. Their specifications disclose an interposer for a glass and plate. One exemplary embodiment of the previous invention comprises an interface configured to interpose between a glass and plate, wherein the interface exhibits an adhesive property and a non-adhesive/non-slip property. In a more specific embodiment of this type, the interface comprises a first material having the non-adhesive/non-slip property and a second material having the adhesive property. A still more specific embodiment of this type includes a third material, between the first and second, that is configured to define a decoration.

Another exemplary embodiment of the previous invention comprises a device suitable for placement on a plate bottom, the device comprising a shaped material having static cling and non-slip properties. The shaped material is configured to receive printing. In a more specific embodiment of this type, the material in fact has printing thereon. As non-limiting support for claims directed to such an embodiment, the disclosure for the previous invention addresses static vinyl and electrostatic adherence.

However, there remains a need in the art for devices and methods for forming the interposer that are alternative or supplemental to those addressed in the '860 patent.

### SUMMARY

Accordingly, exemplary embodiments of the current invention address methods of forming a sheet that includes at least one interposer site. Exemplary embodiments of the current invention are also directed to the sheet itself. One such device exemplary embodiment concerns a sheet with adhesive and non-slip properties and including printing, wherein the sheet is configured to receive still more printing. Exemplary method and device embodiments of the current invention also address additional stages in completing the formation of an interposer.

### BRIEF DESCRIPTION OF THE DRAWINGS

FIG. 1 is a perspective view of an exemplary embodiment within the scope of the current invention.

FIG. 2 is a side view of an exemplary embodiment within the scope of the current invention.

FIG. 3 is a top-down view of an exemplary embodiment within the scope of the current invention.

FIG. 4 is an exploded, perspective view of an exemplary embodiment within the scope of the current invention.

FIG. 5 is a side view of an exemplary embodiment within the scope of the current invention.

FIG. 6 is an exploded, perspective view of an exemplary embodiment within the scope of the current invention.

FIG. 7 is a side view of an exemplary embodiment within the scope of the current invention.

FIG. 8A is a top-down view of an exemplary embodiment within the scope of the current invention.

FIG. 8B is a perspective view of an exemplary embodiment within the scope of the current invention.

FIG. 8C is a perspective view of an alternative exemplary embodiment within the scope of the current invention.

FIG. 9 is a perspective view illustrating an act of an exemplary embodiment within the scope of the current invention.

FIG. 10A is a side view of an exemplary embodiment within the scope of the current invention.

FIG. 10B is a side view of an exemplary embodiment within the scope of the current invention.

FIG. 10C is a side view of an exemplary embodiment within the scope of the current invention.

FIG. 11 is a side view illustrating an act of an exemplary method embodiment within the scope of the current invention.

FIG. 12 is a side view illustrating an act of an exemplary method embodiment within the scope of the current invention.

FIG. 13 is a perspective view of an exemplary embodiment within the scope of the current invention.

FIG. 14 is a perspective view of an exemplary embodiment within the scope of the current invention.

FIG. 15 is a top-down view of an exemplary embodiment within the scope of the current invention.

FIG. 16 is a perspective view of an exemplary embodiment within the scope of the current invention.

FIG. 17 is a perspective view of an exemplary embodiment within the scope of the current invention.

FIG. 18A is a top-down view of an exemplary embodiment within the scope of the current invention.

FIG. 18B is a top-down view of an exemplary embodiment within the scope of the current invention.

FIG. 19 is a perspective view of an exemplary embodiment within the scope of the current invention.

FIG. 20 is a side view of an exemplary embodiment within the scope of the current invention.

FIG. 21 is a perspective view of an exemplary embodiment within the scope of the current invention.

FIG. 22 is a side view of an exemplary embodiment within the scope of the current invention.

FIG. 23 is a side view of an exemplary embodiment within the scope of the current invention.

### DESCRIPTION OF THE PREFERRED EMBODIMENTS

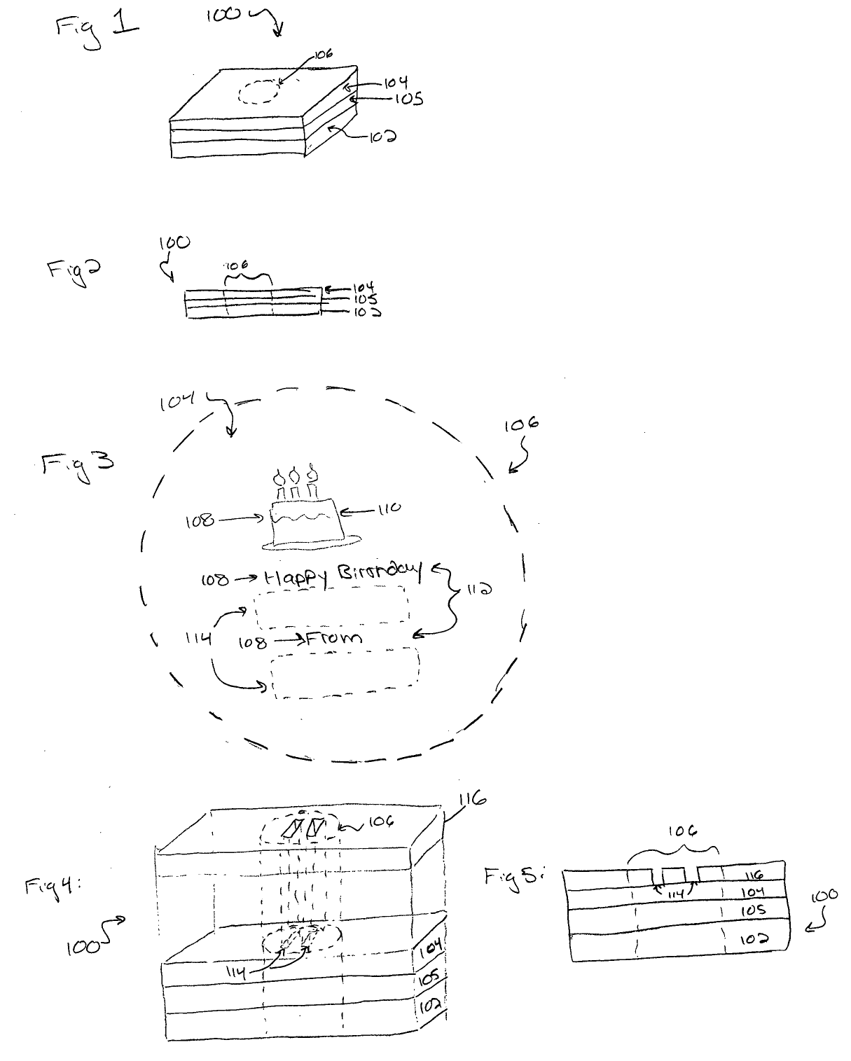

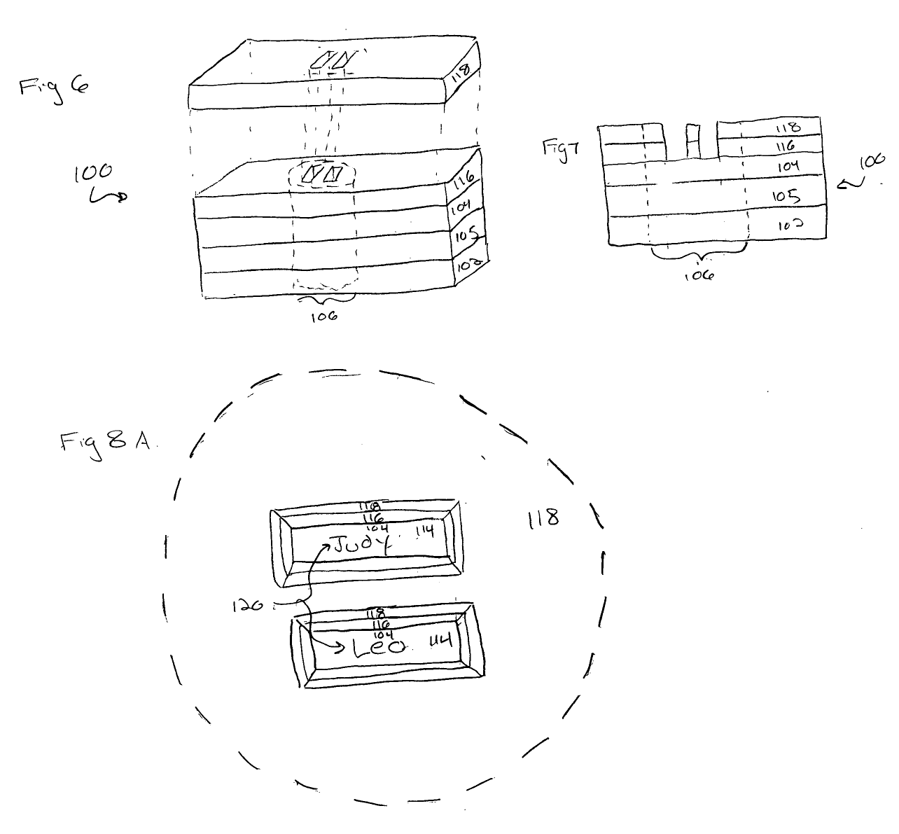

FIG. 1 illustrates a sheet 100 comprising a non-slip layer 102 coupled to a printable layer 104. For purposes of explaining this exemplary embodiment, non-slip layer 102 may be a sheet of Cell-Aire® polyethylene foam manufactured by Sealed Air Corp, and printable layer 104 may be a sheet of typing paper. Both layers 102 and 104 may be sized to accommodate a standard home printer (8.5×11 inches, legal-sized, A4, etc.) and may be coupled using a first adhesive 105 between the two layers. The sheet 100 incorporates at least one interposer site 106, as shown in both FIGS. 1 and 2. FIG. 3 illustrates that the interposer site 106 may include printing 108 on the printable layer 104. The printing 108 may comprise a design 110 as well as text 112. FIG. 3 also illustrates regions 114 on the printable layer 104. Regions 114 may be designated for receiving printing at a later time. Regions 114 may even have at least some printing thereon at this point in the process. However, for purposes of explanation, not limitation, regions 114 will henceforth be referred to as “blank spaces.”

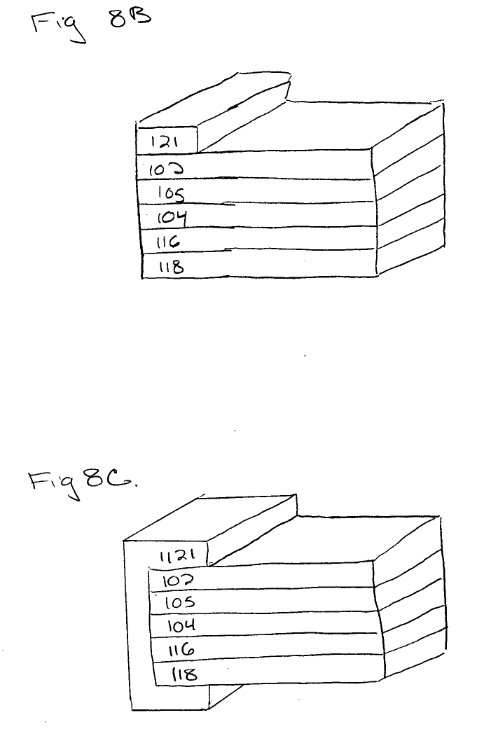

FIG. 4 indicates that sheet 100 further comprises a second adhesive 116 that is over at least one portion of the printable layer 104 yet is patterned to avoid covering the blank spaces 114. FIG. 4 depicts the second adhesive 116 in an exploded view in order to illustrate the alignment of the pattern of the second adhesive 116 with the blank spaces 114. FIG. 5 demonstrates that, in this exemplary embodiment, the second adhesive 116 is on the printable layer 104. It is preferable that the printing 108 be visible through the second adhesive 116. FIGS. 6 and 7 illustrate that a cover layer 118 is provided over the second adhesive 116 and is also patterned to avoid covering the blank spaces 114 of printable layer 104. In this exemplary embodiment, cover layer 118 is another sheet of typing paper. Also in this embodiment, it is preferred that covered sheet 100 undergo a process at some point wherein the area within the interposer site 106 is partially detached from the rest of the sheet 100. The result of such a process is a perforation around the perimeter of the interposer site 106 that extends through the covered sheet 100.

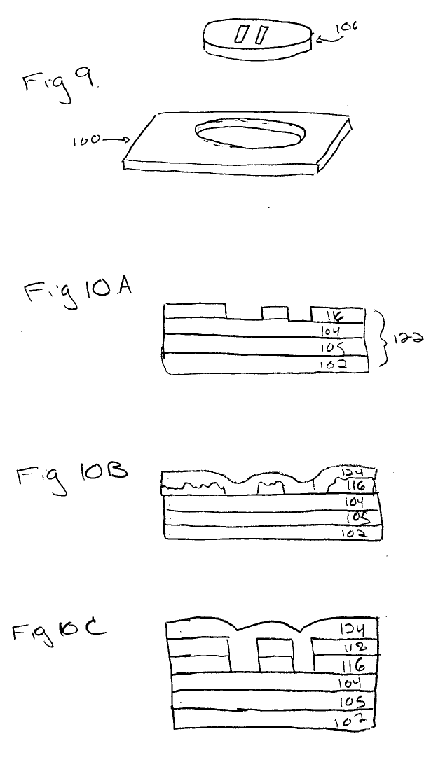

The covered sheet 100 may be fed through a printer (not shown), such as those made by Hewlett-Packard or Lexmark, and the blank spaces 114 of printable layer 104 may receive additional printing 120 from the printer, as illustrated in FIG. 8A. It is noted that direct contact between the non-slip layer 102 and the printer feed mechanism may be problematic. Specifically, at least one component of covered sheet 100 may peel off while attempting to feed the covered sheet 100 through the printer. In such circumstances, it is preferable to attach at least a strip 121 of typing paper to the non-slip layer 102 at the edge of the covered sheet 100 designated to lead into the printer, as seen in FIG. 8B. Additional adhesive not shown in FIG. 8B may be used to attach the strip 121. In the event the bonds between the layers is insufficient to avoid peeling while attempting to feed the covered sheet 100 through the printer, another alternative is to provide a layer of paper 1121 (see FIG. 8C) that wraps around the leading edge of the assembly so that the leading edge is folded paper rather than sheets of paper joined together.

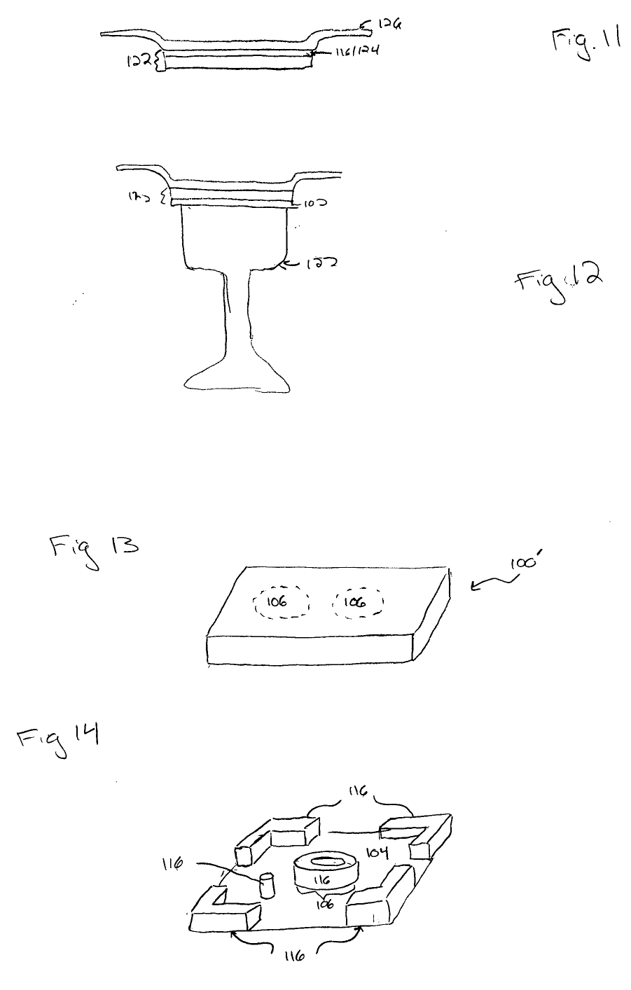

As seen in FIG. 9, the area within the perforated interposer site 106 may then be completely detached from the rest of the sheet 100. As seen in FIG. 10A, the cover layer 118 may be subsequently removed from the interposer site 106, leaving a completed interposer 122. Due to processes such as the cutting and removal of cover layer 118, it is preferable that the second adhesive 116 be in film form rather than sprayed on, as such a film may be more compatible with such processes. Such films are known in the art, and it is stressed that the invention includes within its scope embodiments involving adhesives in film form, spray form, other known forms, and combinations thereof.

FIG. 10B illustrates an option within the scope of this invention, wherein a third adhesive 124 is added in order to better ensure sufficient adhesiveness. As with the second adhesive 116, it is preferable that the printing 108, 120 be visible through the third adhesive 124, in which case it is not necessary to pattern the third adhesive 124. FIG. 10C illustrates yet another option within the scope of this invention, wherein the cover layer 118 is assumed to be transparent to a degree that allows viewing of printing 108. An exemplary material for such a cover layer may be a transparent sheet that is designed to be fed through a printer and has been used in the prior art with an overhead projector. In at least this embodiment, such a cover layer may be retained and the third adhesive 124 may be provided thereover.

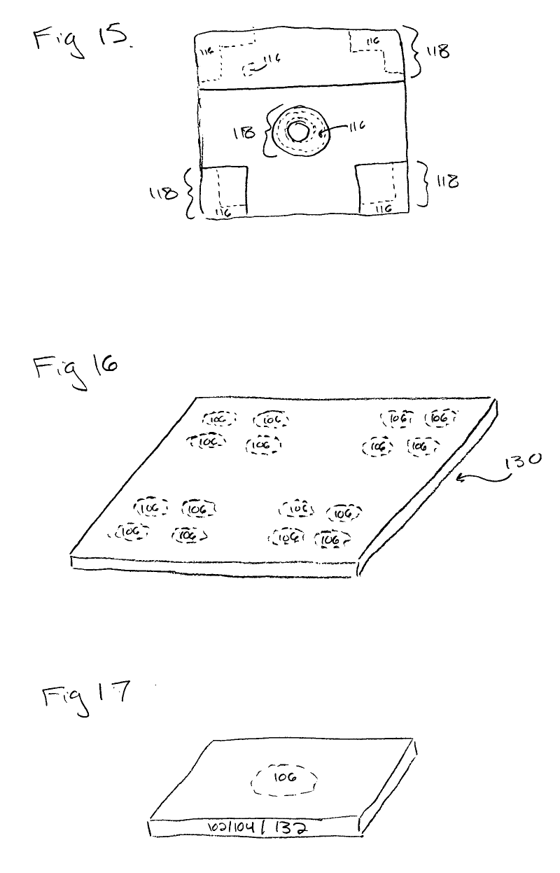

Regardless of which option is chosen, FIG. 11 demonstrates that the resulting interposer 122 may be attached to the bottom of a plate 126 using either or both adhesives 116, 124. It should be noted that if the materials above the printing 108, 120 are of sufficient transparency, the printing 108, 120 may be visible therethrough after attachment to the plate 126. FIG. 12 demonstrates that the interposer 122 may also contact the top of a glass 128 using the non-slip layer 102.

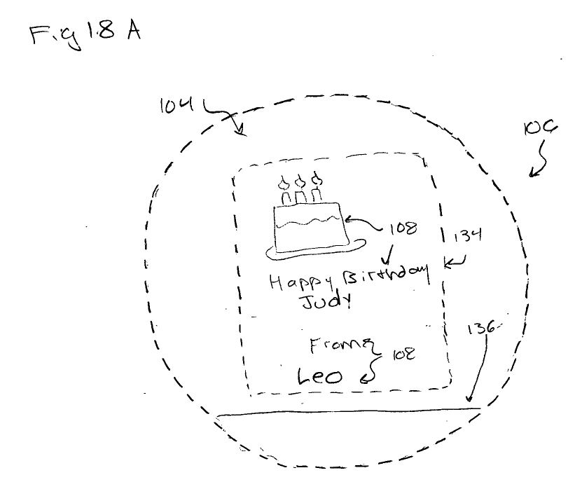

Various modifications of the embodiments addressed above may be made without departing from the spirit and scope of the invention. For example, embodiments are not limited to those involving a sheet 100 defining only a single interposer site 106. FIG. 13 illustrates a sheet 100′ that defines a plurality of interposer sites 106. Moreover, it is not required that the different interposer sites 106 include the same printing 108, 120 or define the same configuration of blank space 114. Further, any of the adhesive layers involved with any of the inventions' embodiments need not define generally continuous layers; rather, such adhesives may be provided in discrete portions 116, as the illustration in FIG. 14 demonstrates. Accordingly, the cover layer 118 may also be provided in discrete portions; although it is preferred that the cover 118 extend at least over all of the adhesive portions 116, as seen in FIG. 15.

Further, embodiments are not limited to those involving a sheet 100 dimensioned to fit inside a standard home printer. Rather, the invention includes within its scope embodiments involving a sheet that may be accommodated by “industrial sized” or commercial printers—larger machines used by professional printers. The invention also includes within its scope embodiments that involve multiple printers, including those of varying sizes.

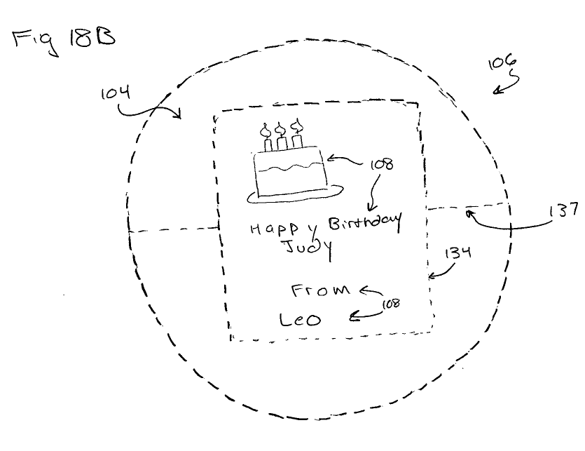

It follows that embodiments include methods and in-process devices involving steps earlier than processes described above. For example, a large sheet 130 (FIG. 16) accommodating a plurality of interposer sites 106 may be fed through a commercial printer, wherein each interposer site 106 receives printing 108 (not shown in FIG. 16) and retains a blank space 114 (not shown). Subsequently the large sheet 130 receives adhesive 116 (not shown) that at least avoids the blank spaces 114. The large sheet 130 then receives a cover 118 (not shown) that at least covers the adhesive and also avoids the blank spaces 114. The perimeter of the interposer sites 106 are perforated and the large sheet is then diced into smaller sheets 100 that contain at least one interposer site and may be processed as described above.

Devices that may be used to accommodate materials larger than those for home use include a topside coater, such as one from Manufacturers Supplies Co., which may be used to apply adhesive to a large sheet 130. Another device is a smoothing press, which again is commercially available from Manufacturers Supplies Co. (model SP) and may be used to combine a plurality of components forming or added to sheet 130. For example, a roll of non-slip material may pass through a coater and then be combined with a roll of printable material in such a smoothing press. At least partial cutting may occur in a die cutting/kisscutting machine (Manufacturers Supplies Co. model GD 151). Such machines may provide complete cutting (or partial cutting including a perforation) for interposer sites, blank spaces on an interposer site, or for defining smaller sheets compatible with a home printer. Manufacturers Supplies Co. model GD 151 die cutting/kisscutting machine also has an option for removing portions having undergone a cutting process and for removing any backing material in order to expose adhesive on a roll of material. The current invention includes within its scope exemplary embodiments concerning the use of such devices as well as the products resulting therefrom.

Moreover, any order of acts that may be inferred from the above description is not a requirement for purposes of limiting the invention. As a non-limiting example, all of the printing may be completed before any full or partial separation of the interposer 122 from its surroundings. Conversely, all of the printing may occur after the interposer is separated from its surroundings. As yet another non-limiting alternative, the printing and separation steps may be interleaved. In one specific example of this type of embodiment, the large sheet 130 is run through a device or series of devices configured to receive the large sheet 130, provide printing 108 on the large sheet 130, provide a patterned adhesive over the large sheet 130, provide a patterned cover over the adhesive, provide perforations around a plurality of interposer sites 106 on the large sheet 130, and cut the large sheet into smaller sheets 100. A sheet 100 may then be run through a device configured to receive sheet 100 and provide additional printing 120 in areas exposed by the patterned adhesive and cover sheet. The interposer 122 may then be removed from sheet 100. Still other orders of printing, adhering, and separating are addressed below.

In such embodiments, the acts of printing, perforating, and completely separating materials may involve the use of more than one device. It also follows that acts within the scope of the invention include those that are automated, those performed manually, and combinations thereof

Additionally, sheet 100 (or 130) need not be a combination of discrete materials. The current invention also includes within its scope embodiments wherein the non-slip material 102 itself also serves as the printable layer 104 and has an adhesive property. This is illustrated in FIG. 17, wherein a non-limiting exemplary material for sheet 132 may be the static vinyl addressed in U.S. Pat. No. 6,138,860. It follows that sheet 132 may undergo various combinations of the printing and separation acts analogous to those addressed above in order to achieve the desired interposer. It further follows that the current invention also includes within its scope embodiments using other static cling materials, including polyethylene (as mentioned above as well as other types), vinyl (as mentioned above as well as other types), Saran Wrap®, polystyrene, etc.

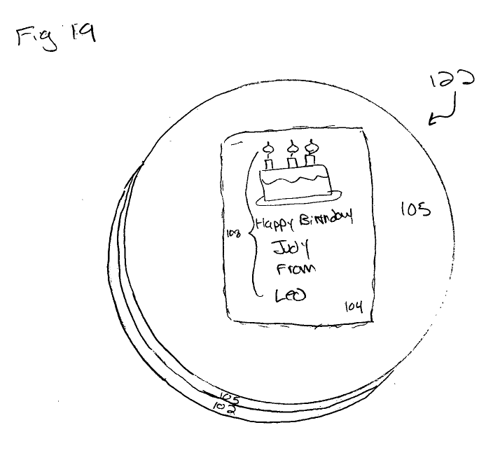

Returning to embodiments with a multi-layered sheet 100, other such embodiments within the scope of the invention use processes such as those described above to achieve a sheet 100 such as that depicted in FIGS. 1 and 2. As mentioned before, the sheet comprises a non-slip layer 102, adhesive 105 thereover, and a printable layer 104 over adhesive 105. FIG. 18 illustrates printing 108 on the printable layer 104 within the interposer site 106. The printing 108 may have resulted from one or more passes through one or more printers. In addition, the sheet 100 in this embodiment has undergone at least partial separation, either before printing, after printing, or between acts of printing. FIG. 18 illustrates a perforation 134 around the printing 108, which may have been provided before printing or separation, after printing or separation, or somewhere in-between one or more printing or perforation acts. Eventually, the perimeter of the interposer site 106 is fully detached from sheet 100. At that point, it is preferred to remove at least one portion of printable layer 104 that is outside of the perforation 134. FIG. 19 demonstrates that this act exposes a portion of adhesive 105, thereby resulting in a completed interposer 122 that is ready to be adhered to the bottom of a plate 126.

Modifications of such embodiments include those wherein additional adhesive is added after removing a portion of printable layer 104. Further, multiple perforations 134 may be provided, with each surrounding a portion of printing 108. In addition, a perforation or full cut 136 (FIG. 18A) through printable layer 104 only (without cutting the materials below) may be provided and may assist in removing the portion of printable layer 104. Such precision cutting is known in the art as “kisscutting.” It is preferable, but not required, that cut 136 be located in the portion of printable layer 104 that is to be removed. An alternative is depicted in FIG. 18B, wherein at least one perforation or full cut 137 extends from a point at the periphery of interposer site 106 to the perforation 134 surrounding a portion of printing 108. In FIG. 18B's particular non-limiting example, the at least one perforation or full cut 137 extends along sections of a diameter of the of interposer site 106 but avoids the portion of printing 108. As for the removing the portion of printable layer 104, it is preferred but not required to conduct that act after the perimeter of the interposer site 106 is fully detached from sheet 100.

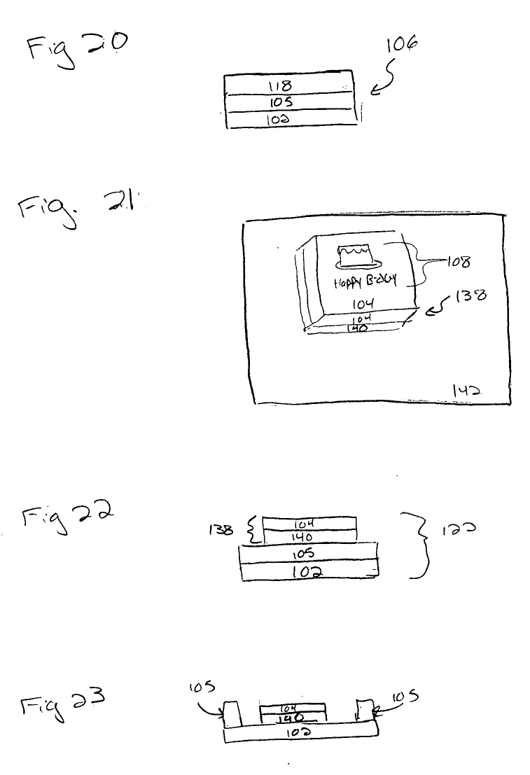

Still other methods within the scope of the invention concern those wherein the processes addressed above are used to provide an interposer site 106 (shown in FIG. 20) comprising a non-slip layer 102 and an adhesive 105 thereover, with a cover layer 118 over the adhesive 105. It is preferred that the adhesion between the non-slip layer 102 and adhesive 105 be greater than the adhesion between adhesive 105 and the cover layer 118. In addition, a sticker or label 138 is provided, as shown in FIG. 21. Label 138 comprises a printable layer 104 with printing 108 on one side and adhesive 140 on the other side. The printing 108 may have resulted from the printable layer 104 having been run through a printer, if such is the case, and if the adhesive 140 had already been applied before printing, it is preferable that the label 138 be temporarily attached to a carrier sheet 142. Mounting the label 138 on a carrier sheet 142 may assist in feeding the label 138 through a printer and in handling the label 138 in general. It is preferred that the adhesion between printable layer 104 and adhesive 140 be greater than the adhesion between the adhesive 140 and carrier sheet 142.

The configuration of printable layer 104, adhesive 140, and carrier sheet 142 is known in the art and is commercially available in the form of printer label sheets, wherein multiple labels may be arrayed on a carrier sheet, fed through a printer, receive printing therein, then be removed from the carrier sheet and adhered to another surface.

In the relevant exemplary embodiments of the current invention, label 138 is removed from the carrier sheet 142 and placed over the non-slip layer 102 after the cover layer 118 has been removed, as illustrated in FIG. 22. It is preferred that label 138 be so dimensioned that at least a portion of adhesive 105 remain exposed after the label 138 is placed thereover. It is even more preferable that the portion of adhesive 105 at the perimeter of the interposer site 106 remain exposed. It is also preferred that, by the time the cover layer 118 is removed, the interposer site 106 has been completely separated from any sheet 100 from which it may have one been a part. If so, a completed interposer is achieved once the label 138 is placed over the non-slip layer 102.

However, the invention does not require separation of the interposer site 106 at that point. Other modifications within the scope of the invention include those wherein the adhesive 105 does not completely cover the non-slip layer 102. In a more specific embodiment of this type (shown in FIG. 23), adhesive 105 is provided only at the perimeter of interposer site; and the adhesive 140 serves to secure the printable layer 104 to the non-slip layer.

One skilled in the art can appreciate that, although specific embodiments of this invention have been described above for purposes of illustration, various modifications may be made without departing from the spirit and scope of the invention. For example, any selection and order of adhering, printing, or separation acts addressed above, as well as their equivalents, may be chosen and combined. Further, the best mode involving such selection and order depends at least in part upon the equipment available. Accordingly, the invention is not limited except as stated in the claims.

1-9. (cancelled).

10. A method of forming an interposer for a glass and plate, comprising:
providing a printable material as at least a portion of said interposer;
sending said printable material through a printer; and
providing a non-slip material as at least a portion of said interposer.

11. The method in claim 10, wherein:
said act of providing a printable material comprises providing a first material; and
said act of providing a non-slip material comprises providing said first material.

12. The method in claim 11, wherein said act of providing a printable material comprises providing a static cling material.

13. The method in claim 12, wherein said act of providing a printable material comprises providing a material selected from a group consisting of polyethylene, vinyl, Saran Wrap®, and polystyrene.

14. The method in claim 12, wherein said act of providing a printable material comprises providing static vinyl.

15. The method in claim 10, wherein:
said act of providing a printable material comprises providing a first material;
said act of providing a non-slip material comprises providing a second material; and
said method further comprises attaching said second material to said first material.

16. (cancelled).

17. The method in claim 15, wherein said attaching act comprises attaching said second material to said first material after said sending act.

18-33. (cancelled).

34. A sheet comprising:
a non-slip printable composition defining
at least one interposer site, and
a region next to at least one interposer site.

35. The sheet in claim 34, wherein said composition has a size selected from a group consisting of 8.5 inches by 11 inches, legal size, or A4.

36. The sheet in claim 34, wherein said non-slip printable composition comprises:
a first printable material; and
a non-slip material adhered to said first printable material.

37. The sheet in claim 36, further comprising printing on said first printable material.

38. The sheet in claim 37, further comprising adhesive over said printable material and clearing at least one region of said printable material.

39. The sheet in claim 38, further comprising a cover over at least all of said adhesive and clearing said region.

40-44. (cancelled).

45. A method of preparing an assembly, comprising:
providing an in-process assembly comprising:
a non-slip material,
an adhesive over said non-slip material, and
a printable material over said adhesive; and
removing a portion of said printable material.

46. The method in claim 45, wherein:
said providing act further comprises providing an assembly defining a periphery;
said method further comprises at least partially cutting around a region within said periphery; and
said removing act comprises removing a portion of said printable material between said region and said periphery.

47. The method in claim 46, further comprising at least partially cutting from a first point on said periphery.

48. The method in claim 47, wherein said act of at least partially cutting comprises at least partially cutting to a second point on said periphery.

49. The method in claim 47, wherein said act of at least partially cutting comprises at least partially cutting to said region.

50. The method in claim 46, wherein said cutting act comprises cutting through the entire thickness of said printable material.

51. The method in claim 50, wherein said cutting act comprises refraining from cutting said non-slip material.

52-53. (cancelled).
